(19) United States
(12) Patent Application Publication
(10) Pub. No.: US 2025/0053079 A1
(43) Pub. Date: Feb. 13, 2025

(54) MASK GENERATION MODEL TRAINING METHOD, MASK GENERATION METHOD AND APPARATUS, AND STORAGE MEDIUM

(71) Applicant: Tencent Technology (Shenzhen) Company Limited, Shenzhen (CN)

(72) Inventors: Xingyu MA, Shenzhen (CN); Shaogang HAO, Shenzhen (CN); Shengyu ZHANG, Shenzhen (CN)

(21) Appl. No.: 18/786,309

(22) Filed: Jul. 26, 2024

Related U.S. Application Data
(63) Continuation of application No. PCT/CN2023/128552, filed on Oct. 31, 2023.

(30) Foreign Application Priority Data
Aug. 10, 2023 (CN) 202311005424.2

(51) Int. Cl. G03F 1/70

(52) U.S. Cl. CPC G03F 1/70

(57) ABSTRACT

This application provides a mask generation model training method performed by a computer device, the method including: obtaining a predicted mask of a target layout of a chip sample; inputting the predicted mask into a photolithography physical model to obtain a wafer pattern corresponding to the predicted mask; determining complexity of the predicted mask of the target layout based on a sum of perimeters of a plurality of patterns included in the target layout of the chip sample and a perimeter of the predicted mask of the target layout; and adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout to obtain a trained mask generation model.

### CROSS-REFERENCE TO RELATED APPLICATIONS

This application is a continuation application of PCT Patent Application No. PCT/CN2023/128552, entitled “MASK GENERATION MODEL TRAINING METHOD, MASK GENERATION METHOD AND APPARATUS, AND STORAGE MEDIUM” filed on Oct. 31, 2023, which claims priority to Chinese Patent Application No. 202311005424.2, entitled “MASK GENERATION MODEL TRAINING METHOD, MASK GENERATION METHOD AND APPARATUS, AND STORAGE MEDIUM” filed with the China National Intellectual Property Administration on Aug. 10, 2023, both of which are incorporated herein by reference in their entirety.

### FIELD OF THE TECHNOLOGY

Embodiments of this application relate to the field of artificial intelligence (AI) technologies, and in particular, to a mask generation model training method, a mask generation method and apparatus, and a storage medium.

### BACKGROUND OF THE DISCLOSURE

A photolithography process is to transfer a geometric figure on a mask to a photoresist on a surface of a wafer. A photoresist processing device spins coating the photoresist on the surface of the wafer, and after step-and-repeat exposure and development processing, a required pattern is formed on the wafer. As a feature size of a very large-scale integrated circuit continues to shorten and is below a light source wavelength used in the photolithography process, an interference phenomenon and a diffraction phenomenon are clearly apparent. As a result, a pattern exposed on a wafer through a mask differs greatly from a required pattern, which seriously affects chip performance, throughput, and yield. To resolve this problem, deep learning technologies are currently applied to various fields of chip design and manufacturing. To ensure high quality of the mask, low complexity of a generated mask needs to be ensured.

In the related art, one method is to optimize the generated mask by using a deep learning algorithm, and another method is to generate the mask by using a pixelation-based inverse lithography technology. However, masks generated in the two methods have high complexity and are difficult to be used in large-scale integrated circuit layout optimization.

### SUMMARY

Embodiments of this application provide a mask generation model training method, a mask generation method and apparatus, and a storage medium, which can reduce complexity of a mask.

According to a first aspect, an embodiment of this application provides a mask generation model training method performed by a computer device, including:
obtaining a training sample set, each training sample including a target layout of a chip sample and a mask of the target layout;
using, for at least one training sample in the training sample set, a target layout of a chip sample in the training sample as an input of a mask generation model, to obtain a predicted mask of the target layout; inputting the predicted mask of the target layout into a photolithography physical model, to obtain a wafer pattern corresponding to the predicted mask of the target layout;
determining complexity of the predicted mask of the target layout based on a sum of perimeters of a plurality of graphics included in the target layout of the chip sample and a perimeter of the predicted mask of the target layout; and
adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model.

According to a second aspect, an embodiment of this application provides a mask generation method, including:
obtaining a target chip layout; and
inputting the target chip layout into a trained mask generation model to output a mask corresponding to the target chip layout, the mask generation model being obtained through training according to the method described in the first aspect.

According to a third aspect, an embodiment of this application provides a computer device, including: a processor and a memory, the memory being configured to store a computer program, and the processor being configured to invoke and run the computer program stored in the memory to perform the method described in the first aspect or the second aspect.

According to a fourth aspect, an embodiment of this application provides a non-transitory computer-readable storage medium, including instructions that, when run on a computer program, cause the computer to perform the method described in the first aspect or the second aspect.

In summary, in the embodiments of this application, a training sample set is first obtained, for at least one training sample in the training sample set, a target layout of a chip sample in the training sample is inputted into a mask generation model to obtain a predicted mask of the target layout, and then the predicted mask of the target layout is inputted into a photolithography physical model to obtain a wafer pattern corresponding to the predicted mask of the target layout. Complexity of the predicted mask of the target layout is determined based on a sum of perimeters of a plurality of graphics included in the target layout of the chip sample and a perimeter of the predicted mask of the target layout. Then, a parameter of the mask generation model is adjusted based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model. In this way, when a model parameter of the mask generation model is adjusted, the model parameter is not only adjusted based on the target layout of the chip sample, the wafer pattern corresponding to the predicted mask of the target layout, the mask of the target layout, and the predicted mask of the target layout, but also adjusted based on the complexity of the predicted mask of the target layout. Therefore, complexity of the mask generated by the mask generation model can be reduced. In addition, since the complexity of the predicted mask of the target layout is determined based on the sum of perimeters of the plurality of graphics included in the target layout of the chip sample and the perimeter of the predicted mask of the target layout, the complexity of the predicted mask of the target layout depends only on shapes of the target layout and the predicted mask of the target layout. Therefore, the mask generation model obtained through training has high transferability, and a calculation amount in a model training process is low.

Further, in the embodiments of this application, the mask generation model is pre-trained, and a model parameter of the pre-trained mask generation model is used as an initial model parameter for subsequent training, so that the calculation amount is reduced, and a model converge is faster.

### BRIEF DESCRIPTION OF THE DRAWINGS

FIG. 1 is a schematic diagram of an implementation scenario of a mask generation model training method and a mask generation method according to an embodiment of this application.

FIG. 2 is a flowchart of a mask generation model training method according to an embodiment of this application.

FIG. 3 is a schematic diagram of a model training process according to an embodiment of this application.

FIG. 4 is a schematic diagram of a target layout of a chip sample, a predicted mask of the target layout of the chip sample, and a contour line of the predicted mask of the target layout of the chip sample.

FIG. 5 is a schematic diagram of a modified edge placement error.

FIG. 6 is a flowchart of a mask generation model training method according to an embodiment of this application.

FIG. 7 is a schematic diagram of a comparison of mask effects according to an embodiment of this application.

FIG. 8 is a schematic diagram of a comparison of mask effects according to an embodiment of this application.

FIG. 9 is a flowchart of a mask generation method according to an embodiment of this application.

FIG. 10 is a schematic structural diagram of a mask generation model training apparatus according to an embodiment of this application.

FIG. 11 is a schematic structural diagram of a mask generation apparatus according to an embodiment of this application.

FIG. 12 is a schematic block diagram of a computer device according to an embodiment of this application.

### DESCRIPTION OF EMBODIMENTS

The technical solutions in the embodiments of this application are clearly and completely described below with reference to accompanying drawings in the embodiments of this application. Apparently, the described embodiments are merely some rather than all of the embodiments of this application. All other embodiments obtained by a person of ordinary skill in the art based on embodiments in the embodiments of this application without creative efforts shall fall within the protection scope of the embodiments of this application.

In the specification, claims, and accompanying drawings of the embodiments of this application, the terms “first”, “second”, and the like are intended to distinguish between similar objects but do not necessarily indicate a specific order or sequence. The data used in such a way is interchangeable in proper circumstances, so that embodiments in the embodiments of this application described herein can be implemented in other orders than the order illustrated or described herein. Moreover, the terms “include”, “contain” and any other variants mean to cover the non-exclusive inclusion. For example, a process, method, system, product, or device that includes a list of operations or units is not necessarily limited to those operations or units, but may include other operations or units not expressly listed or inherent to such a process, method, product, or device.

Before technical solutions of the embodiments of this application are described, relevant knowledge of the technical solutions of the embodiments of this application is explained below:
1. Artificial intelligence (AI): It is a theory, a method, a technology and an application system that uses a digital computer or a machine controlled by the digital computer to simulate, extend, and expand human intelligence, perceive the environment, acquire knowledge, and use knowledge to obtain an optimal result. In other words, the AI is a comprehensive technology in computer science. This technology attempts to understand the essence of intelligence and produce a new intelligent machine that can react in a manner similar to human intelligence. The AI is to study design principles and implementation methods of various intelligent machines, so that the machines have functions of perception, reasoning, and decision-making. The AI technology is a comprehensive discipline, relating to a wide range of fields, and involving both a hardware-level technology and a software-level technology. Basic AI technologies generally include technologies such as a sensor, a dedicated AI chip, cloud computing, distributed storage, a big data processing technology, an operating/interaction system, and electromechanical integration. AI software technologies mainly include several major directions such as a computer vision technology, a speech processing technology, a natural language processing technology, and machine learning/deep learning.
2. Machine learning (ML): It is a multi-field interdiscipline, and relates to a plurality of disciplines such as the probability theory, statistics, the approximation theory, convex analysis, and the algorithm complexity theory. The ML specializes in studying how a computer simulates or implements a human learning behavior to obtain new knowledge or skills, and reorganize an existing knowledge structure, so as to keep improving its performance. The ML is the core of the AI, is a basic way to make a computer intelligent, and is applied to various fields of AI. The ML and the deep learning generally include technologies such as an artificial neural network, a belief network, reinforcement learning, transfer learning, inductive learning, and learning from demonstrations.
3. Deep learning (DL): It is a branch of machine learning, and is an algorithm that attempts to perform high-level abstraction on data by using a plurality of processing layers including a complex structure or including a plurality of nonlinear transformations. The deep learning is learning an intrinsic rule and a representation level of training sample data. Information obtained in these learning processes greatly helps in the interpretation of data such as text, images, and sound. An ultimate objective of the deep learning is to enable a machine to have an analytical learning capability like a human being, and to recognize data such as text, images, and sound. The deep learning is a complex machine learning algorithm, and has effects in speech and image recognition that far exceed those in the previous related art.
Neural network (NN): It is a deep learning model that simulates a structure and a function of a biological neural network in the field of machine learning and cognitive science.

In the related art, complexity of a generated mask is high. To resolve this problem, in the embodiments of this application, when training a mask generation model, for at least one training sample in a training sample set, a target layout of a chip sample in a training sample is inputted into the mask generation model, to obtain a predicted mask of the target layout, and then the predicted mask of the target layout is inputted into a photolithography physical model to obtain a wafer pattern corresponding to the predicted mask of the target layout. Complexity of the predicted mask of the target layout is determined based on a sum of perimeters of a plurality of graphics included in the target layout of the chip sample and a perimeter of the predicted mask of the target layout. Then, a parameter of the mask generation model is adjusted based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model. In this way, in the embodiments of this application, when a model parameter of the mask generation model is adjusted, the model parameter is not only adjusted based on the target layout of the chip sample, the wafer pattern corresponding to the predicted mask of the target layout, the mask of the target layout, and the predicted mask of the target layout, but also adjusted based on the complexity of the predicted mask of the target layout. Therefore, complexity of the mask generated by the mask generation model can be reduced. In addition, since the complexity of the predicted mask of the target layout is determined based on the sum of perimeters of the plurality of graphics included in the target layout of the chip sample and the perimeter of the predicted mask of the target layout, the complexity of the predicted mask of the target layout depends only on shapes of the target layout and the predicted mask of the target layout. Therefore, the mask generation model obtained through training has high transferability, and a calculation amount in a model training process is low.

The embodiments of this application may be applicable to various scenarios that require mask generation, for example, large-scale integrated circuit layout optimization. The mask generation model training method and the mask generation method provided in the embodiments of this application may be loaded into computational lithography software. A chip mask manufacturer may obtain a mask corresponding to a target chip layout by inputting the target chip layout, and the mask has low complexity, so that a mask with high quality can be provided for a subsequent chip photolithography process. For example, specifically, a photolithography mask with low mask complexity may be provided, which significantly reduces calculation time and manufacturing costs of the mask, and increases a process window for generating the mask by the mask generation model. The process window may be understood as tolerances for an exposure amount and a focus deviation. The mask generation model training method and the mask generation method provided in the embodiments of this application may also be extended to fields such as computer vision image generation.

The application scenarios described below are merely configured for describing rather than limiting the embodiments of this application. During specific implementation, the technical solutions provided in the embodiments of this application are flexibly applicable according to an actual requirement.

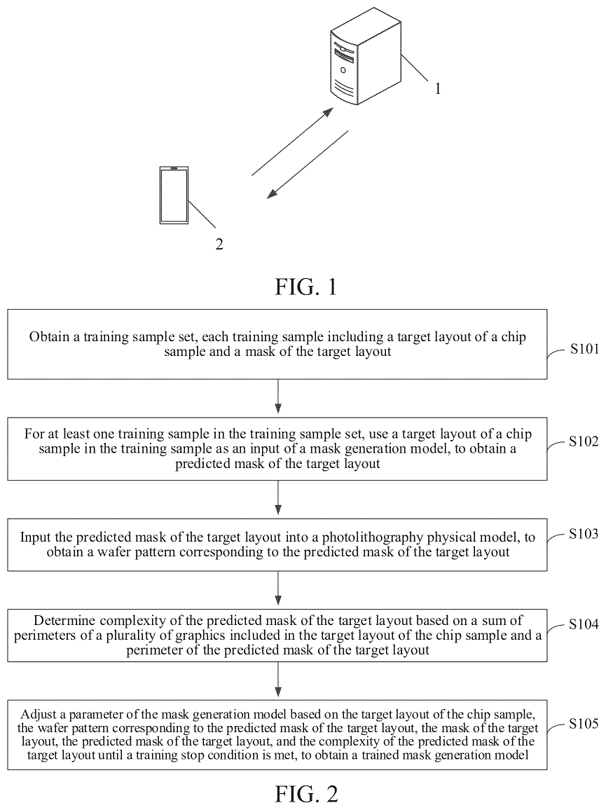

For example, FIG. 1 is a schematic diagram of an implementation scenario of a mask generation model training method and a mask generation method according to an embodiment of this application. As shown in FIG. 1, the implementation scenario of the embodiments of this application involves a server 1 and a terminal device 2. The terminal device 2 may perform data communication on the server 1 through a communication network. The communication network may be a wireless or wired network such as an intranet, the Internet, a global system of mobile communications (GSM), a wideband code division multiple access (WCDMA), a 4G network, a 5G network, Bluetooth, Wi-Fi, or a call network.

In some possible implementations, the terminal device 2 refers to a type of device rich in human-computer interaction manners, capable of accessing the Internet, usually carrying various operating systems, and having a strong processing capability. The terminal device may be a terminal device such as a smartphone, a tablet computer, a portable notebook computer, or a desktop computer, or may be a phone watch, but is not limited thereto. In some embodiments of this application, various applications, for example, photolithography applications, are installed on the terminal device 2.

In some possible implementations, the terminal device 2 includes, but is not limited to, a mobile phone, a computer, a smart speech interaction device, a smart household appliance, an in-vehicle terminal, or the like.

The server 1 in FIG. 1 may be an independent physical server, or may be a server cluster or a distributed system formed by a plurality of physical servers, or may be a cloud server that provides a cloud computing service. This is not limited in the embodiments of this application. In the embodiments of this application, the server 1 may be a backend server of an application installed in the terminal device 2.

In some possible implementations, FIG. 1 exemplarily shows one terminal device and one server. Actually, terminal devices and servers of other numbers may be included. This is not limited in the embodiments of this application.

In some embodiments, when a mask corresponding to a target chip layout needs to be obtained, the server 1 may first train a mask generation model according to the method provided in the embodiments of this application. Specifically, the method may be as follows: obtaining a training sample set, each training sample including a target layout of a chip sample and a mask of the target layout, for at least one training sample in the training sample set, using the target layout of the chip sample in the training sample as an input of the mask generation model to obtain a predicted mask of the target layout; inputting the predicted mask of the target layout into a photolithography physical model to obtain a wafer pattern corresponding to the predicted mask of the target layout; determining complexity of the predicted mask of the target layout based on a sum of perimeters of a plurality of graphics included in the target layout of the chip sample and a perimeter of the predicted mask of the target layout; and adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model. After the trained mask generation model is obtained, a user may upload the target chip layout by using an application for generating the mask installed and run on the terminal device 2. The terminal device 2 sends the uploaded target chip layout to the server 1. After obtaining the target chip layout, the server 1 inputs the target chip layout into the trained mask generation model, and outputs a mask corresponding to the target chip layout. Therefore, the mask corresponding to the target chip layout can be obtained. In an embodiment, the training of the mask generation model may alternatively be performed by the terminal device, and the mask generation method may also be performed by the terminal device. This is not limited in this embodiment.

The technical solution of the embodiments of this application is described in detail in the following;

FIG. 2 is a flowchart of a mask generation model training method according to an embodiment of this application. An execution body of this embodiment of this application is an apparatus having a model training function, for example, a model training apparatus. The model training apparatus may be, for example, a server. As shown in FIG. 2, the method may include the following operations:
S101: Obtain a training sample set, each training sample including a target layout of a chip sample and a mask of the target layout.

Specifically, obtaining the training sample set may be receiving the training sample set, and may alternatively be obtaining a preset number of training samples from a sample data set to form the training sample set. The sample data set may be pre-stored.

Each training sample includes the target layout of the chip sample and the mask of the target layout. A manner of obtaining the sample data set is not limited in this embodiment.

In a possible implementation, the sample data set may be first obtained by using a pixelation-based inverse lithography method. Correspondingly, in S101, obtaining the training sample set may specifically be:
selecting a preset number of pieces of sample data from the sample data set, and forming the training sample set using the preset number of pieces of sample data.
S102: For at least one training sample in the training sample set, use a target layout of a chip sample in the training sample as an input of a mask generation model, to obtain a predicted mask of the target layout.
S103: Input the predicted mask of the target layout into a photolithography physical model, to obtain a wafer pattern corresponding to the predicted mask of the target layout.

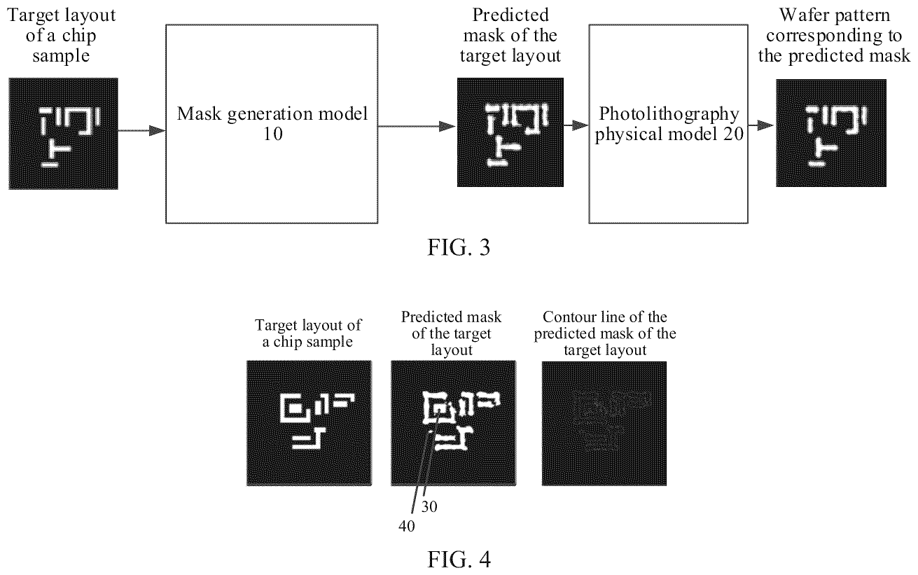

Specifically, FIG. 3 is a schematic diagram of a model training process according to an embodiment of this application. As shown in FIG. 3, after a training sample set is obtained, for at least one training sample in the training sample set, a target layout of a chip sample in the training sample is inputted into a mask generation model 10. The mask generation model 10 outputs a predicted mask of the target layout of the chip sample, and then the predicted mask of the target layout is inputted into a photolithography physical model 20 to output a wafer pattern corresponding to the predicted mask of the target layout. The photolithography physical model is a photolithography physical model with a process parameter being considered. In some embodiments, for each training sample, through the processing process shown in FIG. 3, the target layout of the chip sample, the predicted mask of the target layout of the chip sample, and the wafer pattern corresponding to the predicted mask of the target layout of the chip sample in each training sample may be obtained.
S104: Determine complexity of the predicted mask of the target layout based on a sum of perimeters of a plurality of graphics included in the target layout of the chip sample and a perimeter of the predicted mask of the target layout.

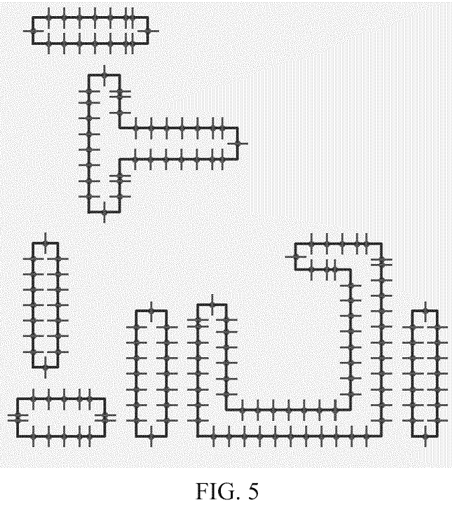

Specifically, the complexity of the mask may be defined as that the mask is substantially free of micro structures such as holes, isolated items, and sawteeth. Therefore, the complexity of the predicted mask of the target layout may be determined based on the sum of the perimeters of the plurality of graphics included in the target layout of the chip sample and the perimeter of the predicted mask of the target layout. In this embodiment, to ensure low complexity of the mask generated by the mask generation model, the complexity of the predicted mask of the target layout needs to be considered when a model parameter is adjusted during model training. Therefore, the complexity of the predicted mask of the target layout needs to be first determined. For case of description, FIG. 4 is a schematic diagram of a target layout of a chip sample, a predicted mask of the target layout of the chip sample, and a contour line of the predicted mask of the target layout of the chip sample. As shown in FIG. 4, the target layout of the chip sample, the predicted mask of the target layout of the chip sample, and the contour line of the predicted mask of the target layout of the chip sample are sequentially from left to right. It can be seen from FIG. 4 that, the predicted mask of the target layout of the chip sample includes a hole and an isolated item. One hole 30 and one isolated item 40 are schematically marked in FIG. 4. The predicted mask of the target layout shown in FIG. 4 further includes another isolated item. The sum of the perimeters of the plurality of graphics included in the target layout refers to a sum of perimeters of all the graphics included in the target layout. The perimeter of the predicted mask of the target layout refers to a sum of lengths of contour lines of the predicted mask of the target layout. That the sum of the perimeters of the plurality of graphics included in the target layout is closer to the perimeter of the predicted mask of the target layout indicates that the complexity of the predicted mask of the target layout is lower. On the contrary, the complexity of the predicted mask of the target layout is higher.

In some embodiments, in a possible implementation, S104 may specifically be as follows:
S1041: Calculate contour lines of the predicted mask of the target layout based on a sum of a square of a first derivative of the predicted mask of the target layout in an x direction and a square of a first derivative of the predicted mask of the target layout in a y direction.
S1042: Perform summation on the contour lines of the predicted mask of the target layout to obtain the perimeter of the predicted mask of the target layout.
S1043: Obtain the sum L of perimeters of the plurality of graphics included in the target layout of the chip sample.
S1044: Calculate the complexity of the predicted mask of the target layout based on a result of dividing the perimeter of the predicted mask of the target layout by L.

In some embodiments, in S1044, calculating the complexity Lₑ of the predicted mask of the target layout based on the result of dividing the perimeter of the predicted mask of the target layout by L may specifically be represented by the following Formula (1):

$${L}_{c} = {\{ \frac{1}{L} {\sum }_{x , y} 2 \times ( {{Mask}_{pred}^{x} ( x , y )}^{2} + {{Mask}_{pred}^{y} ( x , y )}^{2} ) - 1 \}}^{2} , \qquad ( 1 )$$

where

Mask_{pred}^{x}(x, y) represents a first derivative of a predicted mask Mask_{pred} of a target layout in an x direction, Mask_{pred}^{y}(x, y) represents a first derivative of the predicted mask Mask_{pred} of the target layout in a y direction, L represents a sum of perimeters of all graphics included in the target layout, 2×(Mask_{pred}^{x}(x, y)²+Mask_{pred}^{y}(x, y)²) represents a contour line of the predicted mask of the target layout, for example, the predicted mask of the target layout shown in FIG. 3. White represents a light-transmitting region, and black represents a light-shielding region or a light-blocking region. A pixel value of white is 1, and a pixel value of black is 0. Therefore, summation of the contour line of the predicted mask of the target layout is the perimeter of the predicted mask Mask_{pred} of the target layout. When the perimeter of the predicted mask of the target layout is closer to the sum of the perimeters of the plurality of graphics included in the target layout, the complexity of the predicted mask of the target layout is lower, that is, L_{C} is smaller. On the contrary, higher complexity of the predicted mask of the target layout indicates that L_{C} is larger. It can be seen that the complexity of the mask depends only on a shape of the target layout and a shape of the mask, is independent of a specific optical physical model, and may be used in another optical physical model. Specifically, during use of the mask generation model obtained through training in the embodiments of this application, the target chip layout is first obtained, and the target chip layout is inputted into the trained mask generation model, to output the mask corresponding to the target chip layout. During chip photolithography, the mask corresponding to the target chip layout is inputted into the photolithography physical model, to obtain the wafer pattern corresponding to the predicted mask of the target layout. The photolithography physical model herein may be any photolithography physical model, and is not limited to a photolithography physical model used during training of the mask generation model, while in the related art, only the photolithography physical model used during training of the mask generation model can be used, so that transferability of the mask generation model in the embodiments of this application is high.
S105: Adjust a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model.

Specifically, after the complexity of the predicted mask of the target layout is determined, the parameter of the mask generation model may be adjusted based on the target layout of each chip sample in the training sample set, the wafer pattern corresponding to the predicted mask of the target layout of the chip sample, the mask of the target layout of the chip sample, the predicted mask of the target layout of the chip sample, and the complexity of the predicted mask of the target layout of the chip sample that are obtained in a current iteration process, until the training stop condition is met. The parameter of the mask generation model may be adjusted through gradient descent, so that the wafer pattern corresponding to the predicted mask of the target layout of the chip sample and the target layout of the chip sample are as close as possible, the mask of the target layout of the chip sample and the predicted mask of the target layout of the chip sample are as close as possible, and the complexity of the predicted mask of the target layout of the chip sample is reduced (for example, the complexity of the predicted mask is less than a preset threshold), to finally obtain the trained mask generation model.

The mask may also be referred to as a mask, and two concepts are the same.

In some embodiments, in a possible implementation, in S105, adjusting the parameter of the mask generation model based on the target layout of the chip sample, the wafer pattern corresponding to the predicted mask of the target layout, the mask of the target layout, the predicted mask of the target layout, and the complexity of the predicted mask of the target layout may specifically be:
S1051: Construct a first loss function based on the target layout of the chip sample and the wafer pattern corresponding to the predicted mask of the target layout.
S1052: Construct a second loss function based on the mask of the target layout and the predicted mask of the target layout.
S1053: Construct a target loss function based on the first loss function, the second loss function, and the complexity of the predicted mask of the target layout.

In some embodiments, S1053 may specifically be as follows: Calculate the target loss function based on a sum of a product of a first parameter and the first loss function, a product of a second parameter and the complexity of the predicted mask of the target layout, and the second loss function.

In a possible implementation, the target loss function L calculated based on the sum of the product of the first parameter and the first loss function, the product of the second parameter and the complexity of the predicted mask of the target layout, and the second loss function may specifically be represented by the following Formula (2):

$$L = {\vert {Mask}_{pred} - Mask \vert}^{2} + α * {L}_{total} + β * {L}_{c} , \qquad ( 2 )$$

where

Mask represents the mask of the target layout, Mask_{pred} represents the predicted mask of the target layout, Lₜₒₜₐₗ represents the first loss function, |Mask_{pred}−Mask|² represents the second loss function, α is the first parameter, β represents the second parameter, α and β are adjustable parameters, and L_{C} represents the complexity of the predicted mask of the target layout, which may specifically be obtained through calculation by using the foregoing Formula (1).

In a possible implementation, Lₜₒₜₐₗ may be represented by the following Formula (3):

$${L}_{total} = {\sum }_{μ}^{U} {\sum }_{q}^{Q} ξ ( {h}_{μ} ) ξ ( {t}_{q} ) ( {L}_{Aerial} + α {R}_{D} + κ {R}_{TV} + β {L}_{MEPE} ) , \qquad ( 3 )$$

where

ξ(h_{μ}) represents an out of focus process parameter distribution function,

$$ξ ( {h}_{μ} ) = exp \{ - \frac{{( {h}_{μ} )}^{2}}{2 {( {σ}_{h} )}^{2}} \} ,$$

h_{μ} represents that a wafer is located at a distance h from a focal plane of a photolithography machine, and σₕ represents distribution function widening. In some embodiments, in an embodiment, h_{μ}=[h₁, h₂, h₃]=[−80 nm, 0 nm, 80 nm], μ is a subscript of h, U represents that an array length of h_{μ}, which may be 3, and σₕ may be 80; ζ(t_{q}) represents an exposure dose deviation process parameter distribution function,

$$ζ ( {t}_{q} ) = exp \{ - \frac{{( {t}_{q} )}^{2}}{2 {( {σ}_{q} )}^{2}} \} ,$$

t_{q} represents an exposure dose deviation of the photolithography machine, σ_{q} represents distribution function widening. In an embodiment, t_{q}=[t₁, t₂, t₃]=[−0.1, 0.0, 0.1], q is a subscript of t, Q represents an array length of t_{q}, which may be 3 herein, and σ_{q} may be 0.1; α, κ, and β represent adjustable coefficients for balancing relative values of the loss functions, which may be, for example, 0.025, 0.06, and 2 respectively. R_{D} represents a discrete regular term, R_{TV} represents a total variation regular term, L_{MEPE} represents a modified edge placement error loss function, and L_{Aerial} represents an imaging error.

Specifically, the imaging error L_{Aerial} represents an error between a wafer pattern Z corresponding to the predicted mask of the target layout and a target layout Zₜ, which may be obtained through calculation by using the following Formula (4):

$${L}_{Aerial} = \frac{1}{L} {\sum }_{x = 1}^{N} {\sum }_{y = 1}^{N} {( Z ( x , y ; {h}_{μ} , {t}_{q} ) - {Z}_{t} ( x , y ) )}^{γ} , \qquad ( 4 )$$

where

L represents a sum of perimeters of all graphics in a target layout, a dimension of the imaging error is a unit of length, and is consistent with a dimension of a chip node size. γ is an adjustable parameter, which may be, for example, 2. h_{μ} and t_{q} have the same meaning as those in the foregoing Formula (3).

The wafer pattern Z corresponding to the predicted mask of the target layout is obtained through calculation by using a photolithography physical model. The photolithography physical model may be, for example, a Hopkins diffraction photolithography physical model of a partially coherent imaging system. The model obtains a light intensity distribution l(x, y; h_{μ}) imaged on the wafer, and the light intensity distribution is obtained by convolving a mask M and a photolithography system kernel function h. The kernel function is obtained by performing singular value decomposition on a cross transfer coefficient of the photolithography system (for example, a 193 nm annular light source). In some embodiments, the light intensity distribution l(x, y; h_{μ}) can be obtained through calculation by using the following Formula (5):

$$I ( x , y ; {h}_{μ} ) = {\sum }_{k = 1}^{K} {ω}_{k} ( {h}_{μ} ) \vert M ( x , y ) ⊗ {h}_{k} ( x , y ; {h}_{μ} ) {\vert}^{2} , \qquad ( 5 )$$

where

hκ and ωₖ are respectively a k^{th} kernel function and a corresponding weight coefficient after singular value decomposition. In this embodiment of this application, first 24 kernel functions and corresponding weight coefficients after singular value decomposition may be used, that is, K=24, and h_{μ} has the same meaning as that in the foregoing Formula (3).

An imaging pattern on a wafer (namely, the wafer pattern Z) is obtained by transforming the light intensity distribution l(x, y; h_{μ}) through a sigmoid function. The wafer pattern Z may be obtained through calculation by using the following Formula (6):

$$Z ( x , y ; {h}_{μ} , {t}_{q} ) = sig ( I ; {h}_{μ} , {t}_{q} ) = \frac{1}{1 + exp ( - {θ}_{Z} \times ( I ( x , y ; {h}_{μ} ) - {I}_{th} / ( 1 + {t}_{q} ) ) )} , \qquad ( 6 )$$

where

θ_{Z} and Iₜₕ may be 50 and 0.225 respectively, and h_{μ} and t_{q} has the same meaning as in the foregoing Formula (3).

Pixel values of the mask obtained through optimization are in a continuous distribution between 0 and 1, and there is an error between the continuous distribution and a discrete distribution of the binary mask. A difference between the two can be characterized by using the discrete regular term R_{D}, which can be obtained through calculation by using the following Formula (7):

$${R}_{D} = \frac{1}{L} {\sum }_{x = 1}^{N} {\sum }_{y = 1}^{N} [ 1 - {( 1 - 2 M ( x , y ) )}^{2} ] \qquad ( 7 )$$

A total variation regular term R_{TV} may be calculated by using the following Formula (8):

$${R}_{TV} = \frac{1}{L} ( {‖ \frac{\partial f}{\partial x} ‖}_{1} + {‖ \frac{\partial f}{\partial y} ‖}_{1} ) = \frac{1}{L} ( {‖ D ⊕ f ‖}_{1} + {‖ f ⊕ {D}^{T} ‖}_{1} ) , f = \vert M - {Z}_{t} \vert \qquad ( 8 )$$

D represents a matrix first derivative, T represents matrix transpose, ∥.∥₁ represents 1-norm, ⊕ represents a matrix product, M represents the mask, and Zₜ represents the target layout.

The modified edge placement error loss function L_{MEPE} may be obtained through calculation by using the following Formula (9):

$${L}_{MEPE} = {L}_{Aerial - MEPE} + α {R}_{D - MEPE} + κ {R}_{TV - MEPE} , \qquad ( 9 )$$

where

L_{Aerial-MEPE} represents an imaging edge placement error, R_{D-MEPE} represents a discrete regular term of an edge placement error, and R_{TV-MEPE} represents a total variation regular term of the edge placement error.

The definition of the imaging edge placement error L_{Aerial-MEPE} may be the following Formula (10):

$${L}_{Aerial - MEPE} = \frac{1}{L} {\sum }_{x = 1}^{N} {\sum }_{y = 1}^{N} MEPE ⊙ {( Z ( x , y ; {h}_{μ} , {t}_{q} ) - {Z}_{t} ( x , y ) )}^{γ} , \qquad ( 10 )$$

where

an MEPE represents a modified edge placement error. FIG. 5 is a schematic diagram of a modified edge placement error. As shown in FIG. 5, a matrix formed by black short line data points represents the modified edge placement error, a length of the black short line represents a length of the edge placement error, and a plurality of graphics formed by black long lines together form the target layout of the chip sample, and ⊙ represents multiplication of corresponding elements of the matrix formed by the black short line data points.

The definition of a discrete regular term of an edge placement error R_{D-MEPE} may be the following Formula (11):

$${R}_{D - MEPE} = \frac{1}{L} {\sum }_{x = 1}^{N} {\sum }_{y = 1}^{N} [ 1 - {( 1 - 2 M ( x , y ) ⊙ MEPE )}^{2} ] \qquad ( 11 )$$

The definition of a total variation regular term of an edge placement error R_{TV-MEPE} may be the following Formula (12):

$${R}_{TV - MEPE} = \frac{1}{L} ( {‖ \frac{\partial f ⊙ MEPE}{\partial x} ‖}_{1} + {‖ \frac{\partial f ⊙ MEPE}{\partial y} ‖}_{1} ) = \frac{1}{L} ( {‖ D ⊕ ( f ⊙ MEPE ) ‖}_{1} + {‖ ( f ⊙ MEPE ) ⊕ {D}^{T} ‖}_{1} ) \qquad ( 12 )$$

S1044: Adjust the parameter of the mask generation model through a gradient descent algorithm based on the target loss function until the training stop condition is met.

Specifically, the target loss function may be represented by the following Formula (2):

$$L = {\vert {Mask}_{pred} - Mask \vert}^{2} + α * {L}_{total} + β * {L}_{c} , \qquad ( 2 )$$

Mask represents a mask of a target layout, Mask_{pred} represents a predicted mask of a target layout, Lₜₒₜₐₗ represents a first loss function, | Mask_{pred}−Mask|² represents a second loss function, α is a first parameter, β represents a second parameter, α and β are adjustable parameters, and L_{c} represents complexity of the predicted mask of the target layout, which may specifically be obtained through calculation by using the foregoing Formula (1).

The first loss function is obtained through calculation based on the target layout of the chip sample and the wafer pattern corresponding to the predicted mask of the target layout, and the second loss function is obtained through calculation based on the mask of the target layout and the predicted mask of the target layout. The target loss function includes three parts. A target damage function is minimized by the gradient descent algorithm, so that the parameter of the mask generation model is continuously adjusted, and the wafer pattern corresponding to the predicted mask of the target layout of the chip sample and the target layout of the chip sample are as close as possible, and the mask of the target layout of the chip sample and the predicted mask of the target layout of the chip sample are as close as possible. In addition, the complexity of the predicted mask of the target layout of the chip sample is reduced (for example, the complexity of the predicted mask is less than a preset threshold).

In some embodiments, in a possible implementation, S1054 may specifically be as follows:
S10541: Calculate a gradient of the target loss function based on the parameter of the mask generation model in a current iteration process.

Specifically, the target loss function shown in Formula (2) is used as an example, the gradient of the target loss function may be calculated by using the following Formula (13):

$$\frac{\partial L}{\partial w} = \frac{\partial {L}_{fit}}{\partial w} + α \times \frac{\partial {L}_{total}}{\partial {Mask}_{pred}} \times \frac{\partial {Mask}_{pred}}{\partial w} + β \times \frac{\partial {L}_{cl}}{\partial {Mask}_{pred}} \times \frac{\partial {Mask}_{pred}}{\partial w} , \qquad ( 13 )$$

where

w represents a parameter of a mask generation model in a current iteration process, and when the mask generation model is a deep learning model, the parameter of the mask generation model is a neuron weight parameter,

$$\frac{\partial {L}_{cl}}{\partial {Mask}_{pred}}$$

can be obtained by using automatic differentiation, and L_{fit} represents a second loss function.
S10542: Adjust the parameter of the mask generation model based on an optimization direction and an optimization step size of the gradient descent algorithm until the training stop condition is met.

Specifically, the training stop condition may be that a preset number of iterative training times is reached, or may be that a gradient of the target loss function reaches a preset value, or another training stop condition. This is not limited in this embodiment.

In some embodiments, in an embodiment, the mask generation model in this embodiment may be a pre-trained model. Correspondingly, the method in this embodiment may further include:
S106: Obtain a sample data set, each sample data including a target layout of a chip sample and a mask of the target layout of the chip sample.

In some embodiments, in S106, obtaining a sample data set may specifically be: the sample data set is obtained by using a pixelation-based inverse lithography method.

Correspondingly, in S101, obtaining the training sample set may specifically be:
selecting a preset number of pieces of sample data from the sample data set, and forming the training sample set using the preset number of pieces of sample data.
S107: Train a deep learning model based on the sample data set to obtain the mask generation model.

In this embodiment, the mask generation model is pre-trained. A process of pre-training the mask generation model herein may specifically be: obtaining a training sample set, each training sample including a target layout of a chip sample and a mask of the target layout, for at least one training sample in the training sample set, using the target layout of the chip sample in the training sample as an input of a mask generation model to obtain a predicted mask of the target layout; calculating a loss function based on the mask of the target layout of the chip sample and the predicted mask of the target layout of the chip sample; and adjusting a parameter of the mask generation model based on the loss function until a training stop condition is met, to obtain a trained mask generation model.

In this embodiment, pre-training is performed on the mask generation model, and a model parameter of the pre-trained mask generation model is used as an initial model parameter and then trained, so that the model parameter can be first imported, so that the calculation amount is reduced and a model converge is faster.

In some embodiments, the mask generation model in this embodiment may include an encoder and a decoder. The encoder includes a plurality of convolutional neural network layers, and the decoder includes a plurality of deconvolutional neural network layers. A specific structure is described in detail in the following embodiments.

In the mask generation model training method provided in this embodiment, the training sample set is first obtained, for at least one training sample in the training sample set, the target layout of the chip sample in the training sample is inputted into the mask generation model to obtain the predicted mask of the target layout, and then the predicted mask of the target layout is inputted into the photolithography physical model to obtain the wafer pattern corresponding to the predicted mask of the target layout. Complexity of the predicted mask of the target layout is determined based on a sum of perimeters of a plurality of graphics included in the target layout of the chip sample and a perimeter of the predicted mask of the target layout. Then, a parameter of the mask generation model is adjusted based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model. In this way, when a model parameter of the mask generation model is adjusted, the model parameter is not only adjusted based on the target layout of the chip sample, the wafer pattern corresponding to the predicted mask of the target layout, the mask of the target layout, and the predicted mask of the target layout, but also adjusted based on the complexity of the predicted mask of the target layout. Therefore, complexity of the mask generated by the mask generation model can be reduced. In addition, since the complexity of the predicted mask of the target layout is determined based on the sum of perimeters of the plurality of graphics included in the target layout of the chip sample and the perimeter of the predicted mask of the target layout, the complexity of the predicted mask of the target layout depends only on shapes of the target layout and the predicted mask of the target layout. Therefore, the mask generation model obtained through training has high transferability, and a calculation amount in a model training process is low.

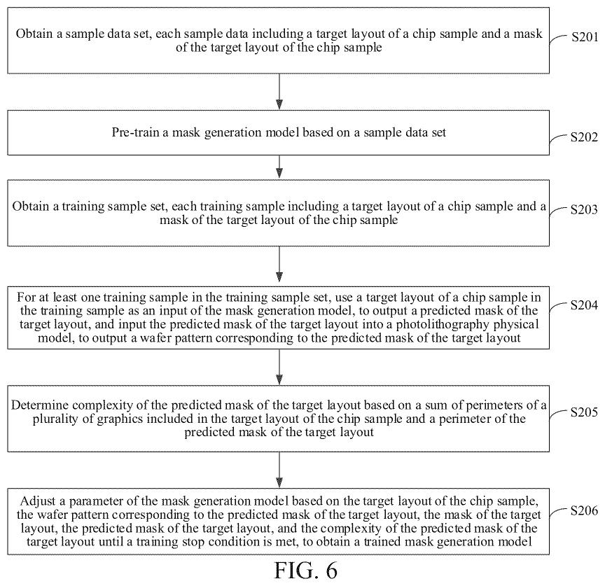

With reference to FIG. 6, a specific embodiment is used below to describe in detail a process of training the mask generation model.

FIG. 6 is a flowchart of a mask generation model training method according to an embodiment of this application. An execution body of the method may be a server. As shown in FIG. 6, the method may include:
S201: Obtain a sample data set, each sample data including a target layout of a chip sample and a mask of the target layout of the chip sample.

Specifically, the sample data set may be obtained by using a pixelation-based inverse lithography method. A specific obtaining process is described in detail in the following embodiments.
S202: Pre-train a mask generation model based on the sample data set.

In this embodiment, the mask generation model is pre-trained. A process of pre-training the mask generation model herein may specifically be: obtaining a training sample set, each training sample including a target layout of a chip sample and a mask of the target layout, for at least one training sample in the training sample set, using the target layout of the chip sample in the training sample as an input of a mask generation model to obtain a predicted mask of the target layout; calculating a loss function based on the mask of the target layout of the chip sample and the predicted mask of the target layout of the chip sample; and adjusting a parameter of the mask generation model based on the loss function until a training stop condition is met, to obtain a trained mask generation model. The mask generation model herein may be a deep learning model. After pre-training is completed, a parameter of the pre-trained mask generation model may be obtained, which may specifically be a neuron weight parameter of the mask generation model.
S203: Obtain a training sample set, each training sample including a target layout of a chip sample and a mask of the target layout of the chip sample.

Specifically, after the mask generation model is obtained through pre-training, a neuron weight parameter of the pre-trained mask generation model is initialized as a to-be-trained mask generation model, that is, the neuron weight parameter of the pre-trained mask generation model is used as an initialized weight parameter of the to-be-trained mask generation model. The obtaining the training sample set may be selecting a preset number of pieces of sample data from the sample data set, and forming the training sample set using the preset number of pieces of sample data.
S204: For at least one training sample in the training sample set, use a target layout of a chip sample in the training sample as an input of the mask generation model, to output a predicted mask of the target layout, and input the predicted mask of the target layout into a photolithography physical model, to output a wafer pattern corresponding to the predicted mask of the target layout.

Specifically, for each training sample in the training sample set, through the processing process shown in FIG. 3, the target layout of the chip sample, the predicted mask of the target layout of the chip sample, and the wafer pattern corresponding to the predicted mask of the target layout of the chip sample in each training sample may be obtained.
S205: Determine complexity of the predicted mask of the target layout based on a sum of perimeters of a plurality of graphics included in the target layout of the chip sample and a perimeter of the predicted mask of the target layout.

Specifically, the complexity of the mask may be defined as that the mask is substantially free of micro structures such as holes, isolated items, and sawteeth. Therefore, the complexity of the predicted mask of the target layout may be determined based on the sum of the perimeters of the plurality of graphics included in the target layout of the chip sample and the perimeter of the predicted mask of the target layout.

In some embodiments, in a possible implementation, S205 may specifically be as follows:
S2051: Calculate contour lines of the predicted mask of the target layout based on a sum of a square of a first derivative of the predicted mask of the target layout in an x direction and a square of a first derivative of the predicted mask of the target layout in a y direction.
S2052: Perform summation on the contour lines of the predicted mask of the target layout to obtain the perimeter of the predicted mask of the target layout.
S2053: Obtain the sum L of perimeters of the plurality of graphics included in the target layout of the chip sample.
S2054: Calculate the complexity of the predicted mask of the target layout based on a result of dividing the perimeter of the predicted mask of the target layout by L.

In some embodiments, in S2054, calculate the complexity of the predicted mask of the target layout based on the result of dividing the perimeter of the predicted mask of the target layout by L may specifically be represented by the foregoing Formula (1).
S206: Adjust a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model.

In some embodiments, in a possible implementation, in S206, adjust the parameter of the mask generation model based on the target layout of the chip sample, the wafer pattern corresponding to the predicted mask of the target layout, the mask of the target layout, the predicted mask of the target layout, and the complexity of the predicted mask of the target layout may specifically be:
S2061: Construct a first loss function based on the target layout of the chip sample and the wafer pattern corresponding to the predicted mask of the target layout.
S2062: Construct a second loss function based on the mask of the target layout and the predicted mask of the target layout.
S2063: Construct a target loss function based on the first loss function, the second loss function, and the complexity of the predicted mask of the target layout.

In a possible implementation, construct a target loss function L based on the first loss function, the second loss function, and the complexity of the predicted mask of the target layout may specifically be represented by the foregoing Formula (2).

In a possible implementation, Lₜₒₜₐₗ can be represented by the foregoing Formula (3).
S2064: Adjust the parameter of the mask generation model through a gradient descent algorithm based on the target loss function until the training stop condition is met.

The first loss function is obtained through calculation based on the target layout of the chip sample and the wafer pattern corresponding to the predicted mask of the target layout, and the second loss function is obtained through calculation based on the mask of the target layout and the predicted mask of the target layout. The target loss function includes three parts. A target damage function is minimized by the gradient descent algorithm, so that the parameter of the mask generation model is continuously adjusted, and the wafer pattern corresponding to the predicted mask of the target layout of the chip sample and the target layout of the chip sample are as close as possible, and the mask of the target layout of the chip sample and the predicted mask of the target layout of the chip sample are as close as possible. In addition, the complexity of the predicted mask of the target layout of the chip sample is reduced (for example, the complexity of the predicted mask is less than a preset threshold).

In some embodiments, in a possible implementation, S2064 may specifically be as follows:
S20641: Calculate a gradient of the target loss function based on the parameter of the mask generation model in a current iteration process.

Specifically, the target loss function shown in Formula (2) is used as an example, the gradient of the target loss function may be calculated by using the following Formula (13):

$$\frac{\partial L}{\partial w} = \frac{\partial {L}_{fit}}{\partial w} + α \times \frac{\partial {L}_{total}}{\partial {Mask}_{pred}} \times \frac{\partial {Mask}_{pred}}{\partial w} + β \times \frac{\partial {L}_{cl}}{\partial {Mask}_{pred}} \times \frac{\partial {Mask}_{pred}}{\partial w} , \qquad ( 13 )$$

where

w represents a parameter of a mask generation model in a current iteration process, and when the mask generation model is a deep learning model, the parameter of the mask generation model is a neuron weight parameter,

$$\frac{\partial {L}_{cl}}{\partial {Mask}_{pred}}$$

can be obtained by using automatic differentiation, and L_{fit} represents a second loss function.
S20642: Adjust the parameter of the mask generation model based on an optimization direction and an optimization step size of the gradient descent algorithm until the training stop condition is met.

Specifically, the foregoing w is adjusted until the training stop condition is met. The training stop condition may be that a preset number of iterative training times is reached, or another training stop condition. This is not limited in this embodiment.

In the mask generation model training method provided in this embodiment, when the mask generation model is trained, the target layout of the chip sample in the training sample is inputted into the mask generation model to obtain the predicted mask of the target layout, and then the predicted mask of the target layout is inputted into the photolithography physical model to obtain the wafer pattern corresponding to the predicted mask of the target layout. The complexity of the predicted mask of the target layout is determined based on the sum of the perimeters of the plurality of graphics included in the target layout of the chip sample and the perimeter of the predicted mask of the target layout, and the target loss function is constructed based on the target layout of the chip sample, the wafer pattern corresponding to the predicted mask of the target layout, the mask of the target layout, the predicted mask of the target layout, and the complexity of the predicted mask of the target layout, to bring the wafer pattern corresponding to the predicted mask of the target layout closer to the target layout of the chip sample by gradient descent, so that the mask of the target layout of the chip sample is as close as possible to the predicted mask of the target layout of the chip sample, In addition, complexity of the predicted mask of the target layout of the chip sample is reduced. Therefore, complexity of the mask generated by the mask generation model obtained through training is reduced. Moreover, since the complexity of the predicted mask of the target layout is determined based on the sum of the perimeters of the plurality of graphics included in the target layout of the chip sample and the perimeter of the predicted mask of the target layout, the complexity of the predicted mask of the target layout depends only on the target layout and a shape of the predicted mask of the target layout. Therefore, the mask generation model obtained through training has high transferability, and a calculation amount in a model training process is low.

The following describes in detail that the sample data set is obtained by using the pixelation-based inverse lithography method. A method of obtaining the sample data set may include:
S1: Determine a loss function.

Specifically, the loss function Lₜₒₜₐₗ may be represented by the following Formula (3):

$${L}_{total} = {Σ}_{μ}^{U} {Σ}_{q}^{Q} ξ ( {h}_{μ} ) ζ ( {t}_{q} ) ( {L}_{Aerial} + α {R}_{D} + κ {R}_{TV} + β {L}_{MEPE} ) , \qquad ( 3 )$$

where

the definition of parameters in the loss function may be found in the description of the embodiment shown in FIG. 1, and details are not described herein again.
S2: Initialize a mask.

Specifically, in this embodiment, a modified chip layout is used, that is, M̅₀=w₁Zₜ+w₂, where Zₜ is a target layout of a chip sample, w₁ and w₂ can be set to 0.98 and 0.1 respectively, so that the calculated gradient is not be too small, which is beneficial to a subsequent gradient descent. In addition, discontinuous optimization of a binary mask is very difficult. Therefore, in this embodiment, a discrete mask optimization problem is transformed into a continuous optimization problem by using the sigmoid function, that

$${M}_{0} = \frac{1}{1 + exp ( - {θ}_{M} \times ( \overline{M} - {M}_{th} ) )} ,$$

where θ_{M} and Mₜₕ can be 4 and 0.225 respectively. The sigmoid function herein may also function as a filter to filter out micro complex structures (islands, hollows, sawteeth, and stretched items) in a generated mask, thereby increasing manufacturability of the mask.
S3: Calculate an optimization direction.

For the steepest descent method, an optimization direction is the gradient

$$\frac{\partial {L}_{total}}{\partial \overline{M}}$$

of the loss function Lₜₒₜₐₗ about the mask. For a conjugate gradient method, an initial descent direction is

$$\frac{\partial {L}_{total}}{\partial \overline{M}} ,$$

a subsequent descent direction retains the optimization direction of a previous step, and a conjugate gradient factor ηₖ is automatically adjusted to avoid optimization stagnation. The gradient of the loss function Lₜₒₜₐₗ may be defined by the following Formula (14):

$$\frac{\partial {L}_{total}}{\partial \overline{M}} = {Σ}_{μ}^{U} {Σ}_{q}^{Q} ξ ( {h}_{μ} ) ζ ( {t}_{q} ) ( \frac{\partial {L}_{Aerial}}{\partial \overline{M}} + α \frac{\partial {R}_{D}}{\partial \overline{M}} + κ \frac{\partial {R}_{TV}}{\partial \overline{M}} + β \frac{\partial {L}_{Aerial - MEPE}}{\partial \overline{M}} + αβ \frac{\partial {R}_{D - MEPE}}{\partial \overline{M}} + κβ \frac{\partial {R}_{TV - MEPE}}{\partial \overline{M}} ) \qquad ( 14 )$$

$$M = \frac{1}{1 + exp ( - {θ}_{M} \times ( \overline{M} - {M}_{th} ) )} ,$$

where θ_{M} and Mₜₕ can be 4 and 0.225 respectively.

The gradient of the imaging error L_{Aerial} may be defined by the following Formula (15):

$$\frac{\partial {L}_{Aerial}}{\partial \overline{M}} = \frac{1}{L} {γ ( Z - {Z}_{t} )}^{y - 1} ⊙ \frac{\partial Z}{\partial \overline{M}} ⊙ \frac{\partial M}{\partial \overline{M}} ↵ = \frac{1}{L} {γθ}_{M} {θ}_{Z} \{ {H}^{flip} ⊗ [ {( Z - {Z}_{t} )}^{y - 1} ⊙ Z ⊙ ( 1 - Z ) ⊙ ( M ⊗ {H}^{⋆} ) ] + {( {H}^{flip} )}^{⋆} ⊗ [ {( Z - {Z}_{t} )}^{y - 1} ⊙ Z ⊙ ( 1 - Z ) ⊙ ( M ⊗ H ) ] \} ⊙ M ⊙ ( 1 - M ) \qquad ( 15 )$$

θ_{M} and θ_{Z} are taken 4 and 50 respectively, H* is a complex conjugate of a photolithography system kernel function H, H^{flip} is obtained by flipping H for 180°, ⊗ represents a matrix convolution operation, and L represents a sum of perimeters of all graphics in a target layout.

The gradient of the discrete regular term R_{D} may be defined by the following Formula (16):

$$\frac{\partial {R}_{D}}{\partial \overline{M}} = \frac{\partial {R}_{D}}{\partial M} ⊙ \frac{\partial M}{\partial \overline{M}} = \frac{1}{L} {θ}_{M} ( - 8 \times M + 4 ) ⊙ M ⊙ ( 1 - M ) \qquad ( 16 )$$

The gradient of the total variation regular term R_{TV} may be defined by the following Formula (17):

$$\frac{\partial {R}_{TV}}{\partial \overline{M}} = \frac{\partial {R}_{TV}}{\partial f} ⊙ \frac{\partial f}{\partial M} ⊙ \frac{\partial M}{\partial \overline{M}} = \frac{1}{L} {θ}_{M} [ {D}^{T} ⊕ sign ( D ⊕ f ) + sign ( f ⊕ {D}^{T} ) ⊕ D ] ⊙ sign ( M - {Z}_{t} ) ⊙ M ⊙ ( 1 - M ) .$$

(17), where

sign represents a sign function, that is, sign(x)=0 and x=0; sign(x)=1, x>0; and sign (x)=−1, x<0

The gradient of the imaging edge placement error L_{Aerial-MEPE} may be defined by the following Formula (18):

$$\frac{\partial {L}_{Aerial - MEPE}}{\partial \overline{M}} = \frac{\partial {L}_{Aerial}}{\partial \overline{M}} ⊙ MEPE \qquad ( 18 )$$

The gradient of the discrete regular term of the edge placement error R_{D-MEPE} may be defined by the following Formula (19):

$$\frac{\partial {R}_{D - MEPE}}{\partial \overline{M}} = \frac{\partial {RM}_{D - MEPE}}{\partial M} ⊙ \frac{\partial M}{\partial \overline{M}} = \frac{1}{L} \times {θ}_{M} ( - 8 \times MEPE ⊙ M + 4 ) ⊙ M ⊙ ( 1 - M ) \qquad ( 19 )$$

The gradient of the total variation regular term of the edge placement error R_{TV-MEPE} may be defined by the following Formula (20):

$$\frac{\partial {R}_{TV - MEPE}}{\partial \overline{M}} = \frac{\partial {R}_{TV - MEPE}}{\partial f} ⊙ \frac{\partial f}{\partial M} ⊙ \frac{\partial M}{\partial \overline{M}} ↵ = \frac{1}{L} {θ}_{M} [ {D}^{T} ⊕ sign ( D ⊕ ( MEPE ⊙ f ) ) + sign ( ( MEPE ⊙ f ) ⊕ {D}^{T} ) ⊕ D ] ⊙ sign ( M - {Z}_{t} ) ⊙ M ⊙ ( 1 - M ) \qquad ( 20 )$$

S4: Update the mask based on the optimization direction.

$${ω}_{k} = \frac{ε}{max ( \vert {V}_{k} \vert )} ,$$

Specifically, an optimization step size may be used where a small value, for example, 0.1, is configured for a step size factor ε. The mask is updated based on the optimization direction, specifically, the pixel value of the mask is updated. The updated pixel value of the mask may exceed 1 or be less than 0. The mask value may be fixed to between 0 and 1 through the sigmoid function. Updated mask

$${M}_{i + 1} = {M}_{i} + {ω}_{k} ⋆ \frac{\partial L}{\partial Mi} ,$$

and Mᵢ is a mask before updating.
S5: Repeat S3 and S4, and optimize a process until a preset number of iterative training times is reached or a gradient reaches an expected value.

Specifically, in a possible implementation, S3 and S4 are repeated, and the optimization process is repeated until a preset number of iterative training times is reached. For example, the preset number of iterative training times is 1000. When the number of iterative training times reaches 1000, the optimization process is stopped. In another possible implementation, S3 and S4 are repeated, and the optimization process is stopped until the gradient reaches an expected value. The expected value of the gradient may be preset.
S6: Perform binarization processing on the optimized mask, that is, the pixel value in the mask exceeds 0.5 to be 1, and otherwise is to be 0.

Finally, the optimized mask is the mask of the target layout. For the target layout of each chip sample, the mask of the target layout of the chip sample is obtained through the foregoing method.

The following further describes a technical effect of the mask generation model training method provided in the embodiments of this application through experimental data.

To verify an effect of the mask generation model training method and apply the mask generation model training method to photolithography mask design of the chip layout, a widely used public photolithography mask data set is selected in this embodiment. A total of 10271 chip layouts and corresponding masks are included in the two data sets. The chip layout is generated meeting a 32 nm process node and a specific design rule. The mask in the photolithography mask data set is obtained through the foregoing pixelation-based inverse lithography method.

The foregoing photolithography mask data set is used, the mask generation model training is performed based on the mask generation model training method provided in the embodiments of this application, to obtain the mask generation model.

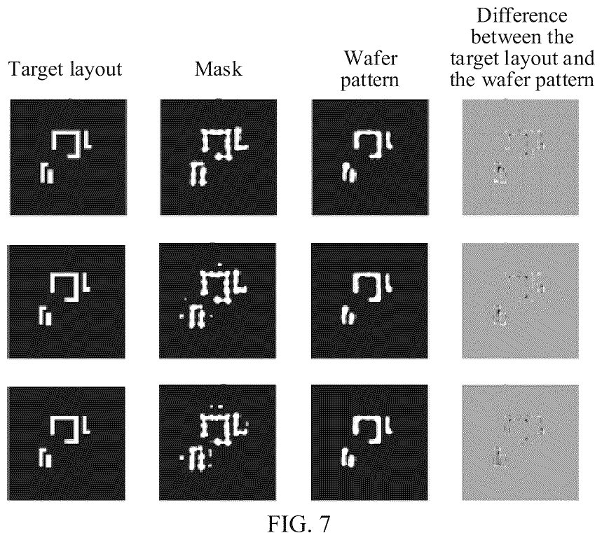

FIG. 7 is a schematic diagram of a comparison of mask effects according to an embodiment of this application. As shown in FIG. 7, four columns in FIG. 7 sequentially represent a target layout, a mask of the target layout, a wafer pattern, and a difference between the target layout and the wafer pattern. For the same target layout (such as a first column of target layouts shown in FIG. 7). A first behavior uses a mask, a wafer pattern, and a difference between the target layout and the wafer pattern that are generated by the mask generation model obtained by the mask generation model training method provided in this embodiment of this application. A second behavior uses a mask, a wafer pattern, and a difference between the target layout and the wafer pattern that are generated by an existing mask optimization algorithm. A third behavior uses a mask, a wafer pattern, and a difference between a target layout and a wafer pattern that are generated by an existing inverse lithography mask optimization algorithm. After comparing the three algorithms, it can be seen that based on the method provided in this embodiment of this application, the generated mask has the least complexity, there are no micro structures such as holes, isolated items, and sawteeth, and the target layout is closest to the wafer pattern.

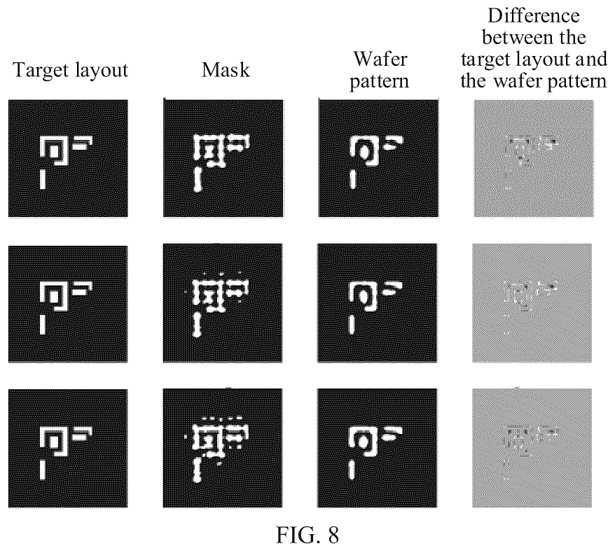

FIG. 8 is a schematic diagram of a comparison of mask effects according to an embodiment of this application. As shown in FIG. 8, four columns in FIG. 8 sequentially represent a target layout, a mask of the target layout, a wafer pattern, and a difference between the target layout and the wafer pattern. For the same target layout (such as a first column of target layouts shown in FIG. 8). A first behavior uses a mask, a wafer pattern, and a difference between the target layout and the wafer pattern that are generated by the mask generation model obtained by the mask generation model training method provided in this embodiment of this application. A second behavior uses a mask, a wafer pattern, and a difference between the target layout and the wafer pattern that are generated by an existing mask optimization algorithm. A third behavior uses a mask, a wafer pattern, and a difference between a target layout and a wafer pattern that are generated by an existing inverse lithography mask optimization algorithm. After comparing the three algorithms, it can be seen that based on the method provided in this embodiment of this application, the generated mask has the least complexity, there are no micro structures such as holes, isolated items, and sawteeth, and the target layout is closest to the wafer pattern. Masks generated by the other two methods are more complex, there are holes, isolated items, or the like.

In some embodiments, the mask generation model in this embodiment may include an encoder and a decoder. The encoder includes a plurality of convolutional neural network layers, and the decoder includes a plurality of deconvolutional neural network layers. In a possible implementation, the encoder includes 8 convolutional neural network layers, and the decoder includes eight deconvolutional neural network layers. Specifically, the eight convolutional layers are respectively formed by eight 3×3 filters, 16 3×3 filters, 32 3×3 filters, 64 3×3 filters, 128 3×3 filters, 256 3×3 filters, 512 3×3 filters, and 1024 3×3 filters. A batch normalization layer is established after each convolutional layer and a subsequent activation function uses a modified linear unit (ReLU). After a target layout of a chip with dimensions (256, 256, 1) is inputted, a final output with dimensions (1, 1, 1024) is used as an input of the decoder. The first seven deconvolutional layers are respectively formed by 1024 3×3 filters, 512 3×3 filters, 256 3×3 filters, 128 3×3 filters, 64 3×3 filters, 32 3×3 filters, and 16 3×3 filters sequentially. After each deconvolutional layer, a batch normalization layer is established and a Leaky modified linear unit (Leaky-ReLU) is used as a subsequent activation function. Finally, a deconvolutional neural network layer including eight 3×3 filters and a sigmoid activation function gives a predicted mask with dimensions (256, 256, 1) and values 0 to 1, and then binarization processing is performed on the mask to obtain a final mask.

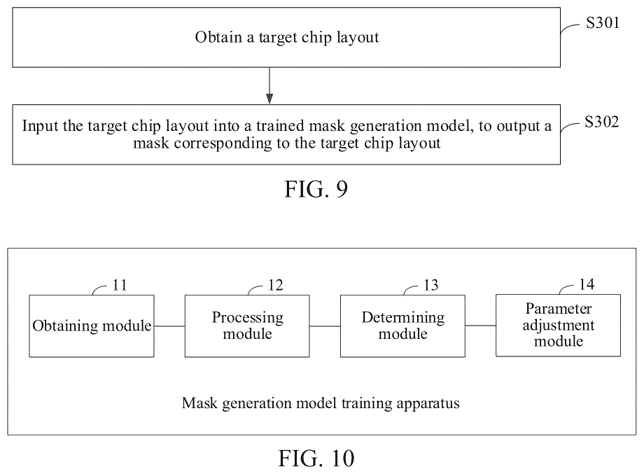

FIG. 9 is a flowchart of a mask generation method according to an embodiment of this application. An execution body of the method may be a server. As shown in FIG. 9, the method may include:
S301: Obtain a target chip layout.
S302: Input the target chip layout into a trained mask generation model, to output a mask corresponding to the target chip layout.

The mask generation model is obtained through training based on the method in the embodiment shown in FIG. 2 or FIG. 6.

Based on the mask generation method provided in this embodiment, a mask with low complexity can be generated through the mask generation model, so that a mask with high quality can be provided for a subsequent chip photolithography process, thereby reducing calculation time and manufacturing costs of the mask.

FIG. 10 is a schematic structural diagram of a mask generation model training apparatus according to an embodiment of this application. As shown in FIG. 11, the apparatus may include: an obtaining module 11, a processing module 12, a determining module 13, and a parameter adjustment module 14.

The obtaining module 11 is configured to obtain a training sample set, each training sample including a target layout of a chip sample and a mask of the target layout.

The processing module 12 is configured to use, for at least one training sample in the training sample set, a target layout of a chip sample in the training sample as an input of a mask generation model.

The processing module 12 is further configured to obtain a predicted mask of the target layout, and input the predicted mask of the target layout into a photolithography physical model, to obtain a wafer pattern corresponding to the predicted mask of the target layout.

The determining module 13 is configured to determine complexity of the predicted mask of the target layout based on a sum of perimeters of a plurality of graphics included in the target layout of the chip sample and a perimeter of the predicted mask of the target layout.

The parameter adjustment module 14 is configured to adjust a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model.

In an embodiment, the determining module 13 is configured to: calculate contour lines of the predicted mask of the target layout based on a sum of a square of a first derivative of the predicted mask of the target layout in an x direction and a square of a first derivative of the predicted mask of the target layout in a y direction;
perform summation on the contour lines of the predicted mask of the target layout to obtain the perimeter of the predicted mask of the target layout;
obtain the sum L of perimeters of the plurality of graphics included in the target layout of the chip sample; and
calculate the complexity of the predicted mask of the target layout based on a result of dividing the perimeter of the predicted mask of the target layout by L.

In an embodiment, the parameter adjustment module 14 is configured to:
construct a first loss function based on the target layout of the chip sample and the wafer pattern corresponding to the predicted mask of the target layout;
construct a second loss function based on the mask of the target layout and the predicted mask of the target layout;
construct a target loss function based on the first loss function, the second loss function, and the complexity of the predicted mask of the target layout; and
adjust the parameter of the mask generation model through a gradient descent algorithm based on the target loss function until the training stop condition is met.

In an embodiment, the parameter adjustment module 14 is further configured to:
calculate the target loss function based on a sum of a product of a first parameter and the first loss function, a product of a second parameter and the complexity of the predicted mask of the target layout, and the second loss function.

In an embodiment, the parameter adjustment module 14 is further configured to:
calculate a gradient of the target loss function based on the parameter of the mask generation model in a current iteration process; and
adjust the parameter of the mask generation model based on an optimization direction and an optimization step size of the gradient descent algorithm until the training stop condition is met.

In an embodiment, the mask generation model is a pre-trained model, and the obtaining module 11 is further configured to:
obtain a sample data set, each sample data including the target layout of the chip sample and the mask of the target layout; and
the processing module 12 is further configured to train a deep learning model based on the sample data set to obtain the mask generation model.

In an embodiment, the obtaining module 11 is further configured to:
obtain the sample data set by using a pixelation-based inverse lithography method; and
select a preset number of pieces of sample data from the sample data set, and forming the training sample set using the preset number of pieces of sample data.

In an embodiment, the mask generation model includes an encoder and a decoder. The encoder includes a plurality of convolutional neural network layers, and the decoder includes a plurality of deconvolutional neural network layers.

FIG. 11 is a schematic structural diagram of a mask generation apparatus according to an embodiment of this application. As shown in FIG. 11, the apparatus may include: an obtaining module 21 and a processing module 22.

The obtaining module 21 is configured to obtain a target chip layout.

The processing module 22 is configured to input the target chip layout into a trained mask generation model, to output a mask corresponding to the target chip layout, the mask generation model being obtained through training according to the method in the embodiment shown in FIG. 1.

Apparatus embodiments and method embodiments may correspond to each other. For a similar description, reference may be made to the method embodiments. To avoid repetition, details are not described herein again. Specifically, the mask generation model training apparatus shown in FIG. 10 or the mask generation apparatus shown in FIG. 11 may perform a method embodiment corresponding to the terminal device or the server, and the foregoing and other operations and/or functions of the modules in the apparatus are respectively intended to implement the method embodiment corresponding to the terminal device or the server. For brevity, details are not described herein again.

The mask generation model training apparatus and the mask generation apparatus of the embodiments of this application are described above with reference to the accompanying drawings from a perspective of a functional module. The functional module may be implemented in hardware form, or may be implemented in software form of instructions, or may be implemented through a combination of hardware and software modules. Specifically, operations of the method embodiments in the embodiments of this application may be completed by instructions in the form of hardware integrated logic circuits and/or software in the processor, and operations of the methods disclosed with reference to the embodiments of this application may be directly performed and completed by using a hardware decoding processor, or may be performed and completed by using a combination of hardware and software modules in the decoding processor. In some embodiments, the software module may be located in a mature storage medium in the art, such as a random access memory, a flash memory, a read-only memory, a programmable read-only memory, an electrically-erasable programmable memory, and a register. The storage medium is located in the memory. The processor reads information in the memory and completes the operations of the foregoing method embodiments in combination with hardware thereof.

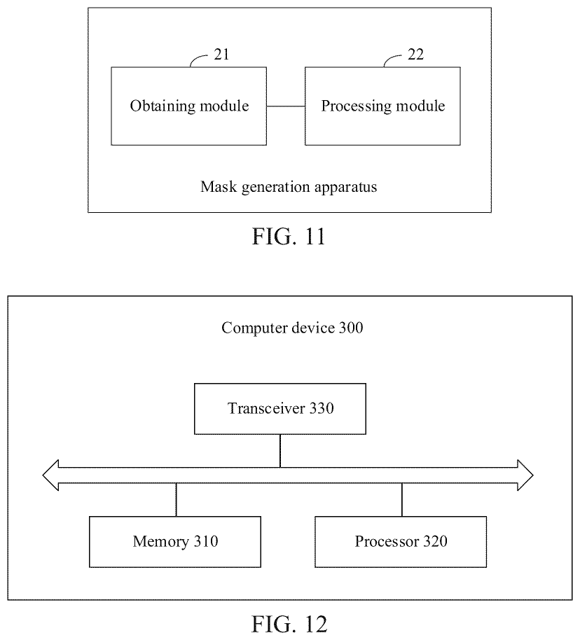

FIG. 12 is a schematic block diagram of a computer device 300 according to an embodiment of this application.

As shown in FIG. 12, the computer device 300 may include:
a memory 310 and a processor 320. The memory 310 is configured to store a computer program and transmit program code to the processor 320. In other words, the processor 320 may invoke and run the computer program from the memory 310 to implement the method in the embodiments of this application.

For example, the processor 320 may be configured to perform the foregoing method embodiment based on instructions in the computer program.

In some embodiments of the embodiments of this application, the processor 320 may include, but is not limited to:
a general processor, a digital signal processor (DSP), an application specific integrated circuit (ASIC), a field programmable gate array (FPGA), another programmable logic device, a discrete gate, a transistor logic device, a discrete hardware component, or the like.

In some embodiments of the embodiments of this application, the memory 310 includes, but is not limited to:
a non-volatile memory and/or a volatile memory. The non-volatile memory may be a read-only memory (ROM), a programmable read-only memory (PROM), an erasable programmable read-only memory (EPROM), an electrically erasable programmable read-only memory (EEPROM), or a flash memory. The volatile memory may be a random access memory (RAM) that is used as an external cache. Through example but not limitative description, many forms of RAMs may be used, for example, a static random access memory (SRAM), a dynamic random access memory (DRAM), a synchronous dynamic random access memory (SDRAM), a double data rate synchronous dynamic random access memory (DDR SDRAM), an enhanced synchronous dynamic random access memory (ESDRAM), a synchronous link dynamic random access memory (SLDRAM), and a direct rambus dynamic random access memory (DR RAM).

In some embodiments of the embodiments of this application, the computer program may be divided into one or more modules, and the one or more modules are stored in the memory 310 and executed by the processor 320 to perform the methods provided in the embodiments of this application. The one or more modules may be a series of computer program instruction segments capable of performing a particular function, and the instruction segments are configured for describing the execution of the computer program in the electronic device.

As shown in FIG. 12, the computer device may further include:
a transceiver 330. The transceiver 330 may be connected to the processor 320 or the memory 310.

The processor 320 may control the transceiver 330 to communicate with another device, and specifically, may send information or data to another device or receive information or data sent by another device. The transceiver 330 may include a transmitter and a receiver. The transceiver 330 may further include an antenna, and a number of antennas may be one or more.

Various components of the electronic device are connected to each other by using a bus system. In addition to including a data bus, the bus system further includes a power bus, a control bus, and a status signal bus.

An embodiment of this application further provides a computer storage medium, having a computer program stored therein. When the computer program is executed by a computer, the computer is enabled to perform the method according to the foregoing method embodiments. In other words, an embodiment of this application further provides a computer program product including instructions. When the instructions executed by a computer, the computer is caused to perform the method according to the foregoing method embodiments.

When software is used to implement embodiments, all or a part of the embodiments may be implemented in a form of a computer program product. The computer program product includes one or more computer instructions. When the program instruction of the computer is loaded and executed on the computer program, all or some of the steps are generated according to the process or function described in the embodiments of this application. The computer may be a general-purpose computer, a special-purpose computer, a computer network, or another programmable apparatus. The computer instructions may be stored in a computer-readable storage medium or transmitted from one computer-readable storage medium to another computer-readable storage medium. For example, the computer instructions may be transmitted from one website, computer, server or data center to another website, computer, server or data center in a wired (for example, a coaxial cable, an optical fiber or a digital subscriber line (DSL)) or wireless (for example, infrared, wireless or microwave) manner. The computer-readable storage medium may be any usable medium accessible by the computer, or a data storage device, for example, a server or a data center, integrating one or more usable media. The available medium may be a magnetic medium (such as a floppy disk, a hard disk, or a magnetic tape), an optical medium (such as a digital video disc (DVD)), a semiconductor medium (such as a solid state disk (SSD)) or the like.

A person of ordinary skill in the art may be aware that, in combination with the examples described in the embodiments disclosed in this specification, modules and algorithm steps may be implemented by electronic hardware or a combination of computer software and electronic hardware. Whether the functions are performed by hardware or software depends on particular applications and design constraint conditions of the technical solutions. A person skilled in the art may use different methods to implement the described functions for each particular application, but it is not to be considered that the implementation goes beyond the scope of the embodiments of this application.

In the several embodiments provided in the embodiments of this application, the disclosed system, apparatus, and method may be implemented in other manners. For example, the described apparatus embodiment is merely exemplary. For example, the module division is merely logical function division and may be other division in actual implementation. For example, a plurality of modules or components may be combined or integrated into another system, or some features may be ignored or not performed. In addition, the displayed or discussed mutual couplings or direct couplings or communication connections may be implemented by using some interfaces. The indirect couplings or communication connections between the apparatuses or modules may be implemented in electronic, mechanical, or other forms.

The modules described as separate parts may or may not be physically separate, and parts displayed as modules may or may not be physical modules, may be located in one position, or may be distributed on a plurality of network units. Some or all of the modules may be selected according to actual requirements to implement the objectives of the solutions of the embodiments. For example, functional modules in the embodiments of this application may be integrated into one processing module, or each of the modules may exist alone physically, or two or more modules may be integrated into one module.

The foregoing descriptions are merely specific implementations of the embodiments of this application, but are not intended to limit the protection scope of the embodiments of this application. Any variation or replacement readily figured out by a person skilled in the art within the technical scope disclosed in the embodiments of this application shall fall within the protection scope of the embodiments of this application. Therefore, the protection scope of the embodiments of this application shall be subject to the protection scope of the claims.

What is claimed is:

1. A mask generation model training method performed by a computer device, the method comprising:
obtaining a training sample set, each training sample comprising a target layout of a chip sample and a mask of the target layout;
using, for at least one training sample in the training sample set, a target layout of a chip sample in the training sample as an input of a mask generation model, to obtain a predicted mask of the target layout;
inputting the predicted mask of the target layout into a photolithography physical model, to obtain a wafer pattern corresponding to the predicted mask of the target layout;
determining complexity of the predicted mask of the target layout based on a sum of perimeters of a plurality of graphics comprised in the target layout of the chip sample and a perimeter of the predicted mask of the target layout; and
adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model.

2. The method according to claim 1, wherein the determining complexity of the predicted mask of the target layout based on a sum of perimeters of a plurality of graphics comprised in the target layout of the chip sample and a perimeter of the predicted mask of the target layout comprises:
calculating contour lines of the predicted mask of the target layout based on a sum of a square of a first derivative of the predicted mask of the target layout in an x direction and a square of a first derivative of the predicted mask of the target layout in a y direction;
performing summation on the contour lines of the predicted mask of the target layout to obtain the perimeter of the predicted mask of the target layout;
obtaining the sum L of perimeters of the plurality of graphics comprised in the target layout of the chip sample; and
calculating the complexity of the predicted mask of the target layout based on a result of dividing the perimeter of the predicted mask of the target layout by L.

3. The method according to claim 1, wherein the adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met comprises:
constructing a first loss function based on the target layout of the chip sample and the wafer pattern corresponding to the predicted mask of the target layout;
constructing a second loss function based on the mask of the target layout and the predicted mask of the target layout;
constructing a target loss function based on the first loss function, the second loss function, and the complexity of the predicted mask of the target layout; and
adjusting the parameter of the mask generation model through a gradient descent algorithm based on the target loss function until the training stop condition is met.

4. The method according to claim 3, wherein the constructing a target loss function based on the first loss function, the second loss function, and the complexity of the predicted mask of the target layout comprises:
calculating the target loss function based on a sum of a product of a first parameter and the first loss function, a product of a second parameter and the complexity of the predicted mask of the target layout, and the second loss function.

5. The method according to claim 3, wherein the adjusting the parameter of the mask generation model through a gradient descent algorithm based on the target loss function until the training stop condition is met comprises:
calculating a gradient of the target loss function based on the parameter of the mask generation model in a current iteration process; and
adjusting the parameter of the mask generation model based on an optimization direction and an optimization step size of the gradient descent algorithm until the training stop condition is met.

6. The method according to claim 1, wherein the mask generation model is a pre-trained model, and the method further comprises:
obtaining a sample data set, each sample data comprising the target layout of the chip sample and the mask of the target layout; and
training a deep learning model based on the sample data set to obtain the mask generation model.

7. The method according to claim 6, wherein the obtaining a sample data set comprises:
obtaining the sample data set by using a pixelation-based inverse lithography method; and
the obtaining a training sample set comprises:
selecting a preset number of pieces of sample data from the sample data set, and forming the training sample set using the preset number of pieces of sample data.

8. The method according to claim 1, wherein the mask generation model comprises an encoder and a decoder, the encoder comprises a plurality of convolutional neural network layers, and the decoder comprises a plurality of deconvolutional neural network layers.

9. A computer device, comprising:
a processor and a memory, the memory being configured to store a computer program that, when executed by the processor, causes the computer device to perform a mask generation model training method including:
obtaining a training sample set, each training sample comprising a target layout of a chip sample and a mask of the target layout;
using, for at least one training sample in the training sample set, a target layout of a chip sample in the training sample as an input of a mask generation model, to obtain a predicted mask of the target layout;
inputting the predicted mask of the target layout into a photolithography physical model, to obtain a wafer pattern corresponding to the predicted mask of the target layout;
determining complexity of the predicted mask of the target layout based on a sum of perimeters of a plurality of graphics comprised in the target layout of the chip sample and a perimeter of the predicted mask of the target layout; and
adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model.

10. The computer device according to claim 9, wherein the determining complexity of the predicted mask of the target layout based on a sum of perimeters of a plurality of graphics comprised in the target layout of the chip sample and a perimeter of the predicted mask of the target layout comprises:
calculating contour lines of the predicted mask of the target layout based on a sum of a square of a first derivative of the predicted mask of the target layout in an x direction and a square of a first derivative of the predicted mask of the target layout in a y direction;
performing summation on the contour lines of the predicted mask of the target layout to obtain the perimeter of the predicted mask of the target layout;
obtaining the sum L of perimeters of the plurality of graphics comprised in the target layout of the chip sample; and
calculating the complexity of the predicted mask of the target layout based on a result of dividing the perimeter of the predicted mask of the target layout by L.

11. The computer device according to claim 9, wherein the adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met comprises:
constructing a first loss function based on the target layout of the chip sample and the wafer pattern corresponding to the predicted mask of the target layout;
constructing a second loss function based on the mask of the target layout and the predicted mask of the target layout;
constructing a target loss function based on the first loss function, the second loss function, and the complexity of the predicted mask of the target layout; and
adjusting the parameter of the mask generation model through a gradient descent algorithm based on the target loss function until the training stop condition is met.

12. The computer device according to claim 11, wherein the constructing a target loss function based on the first loss function, the second loss function, and the complexity of the predicted mask of the target layout comprises:
calculating the target loss function based on a sum of a product of a first parameter and the first loss function, a product of a second parameter and the complexity of the predicted mask of the target layout, and the second loss function.

13. The computer device according to claim 11, wherein the adjusting the parameter of the mask generation model through a gradient descent algorithm based on the target loss function until the training stop condition is met comprises:
calculating a gradient of the target loss function based on the parameter of the mask generation model in a current iteration process; and
adjusting the parameter of the mask generation model based on an optimization direction and an optimization step size of the gradient descent algorithm until the training stop condition is met.

14. The computer device according to claim 9, wherein the mask generation model is a pre-trained model, and the method further comprises:
obtaining a sample data set, each sample data comprising the target layout of the chip sample and the mask of the target layout; and
training a deep learning model based on the sample data set to obtain the mask generation model.

15. The computer device according to claim 14, wherein the obtaining a sample data set comprises:
obtaining the sample data set by using a pixelation-based inverse lithography method; and
the obtaining a training sample set comprises:
selecting a preset number of pieces of sample data from the sample data set, and forming the training sample set using the preset number of pieces of sample data.

16. The computer device according to claim 9, wherein the mask generation model comprises an encoder and a decoder, the encoder comprises a plurality of convolutional neural network layers, and the decoder comprises a plurality of deconvolutional neural network layers.

17. A non-transitory computer-readable storage medium, comprising a computer program, the computer program, when executed by a processor of a computer device, causing the computer device to perform a method for designing component arrangement on a chip layout including:
obtaining a training sample set, each training sample comprising a target layout of a chip sample and a mask of the target layout;
using, for at least one training sample in the training sample set, a target layout of a chip sample in the training sample as an input of a mask generation model, to obtain a predicted mask of the target layout;
inputting the predicted mask of the target layout into a photolithography physical model, to obtain a wafer pattern corresponding to the predicted mask of the target layout;
determining complexity of the predicted mask of the target layout based on a sum of perimeters of a plurality of graphics comprised in the target layout of the chip sample and a perimeter of the predicted mask of the target layout; and
adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met, to obtain a trained mask generation model.

18. The non-transitory computer-readable storage medium according to claim 17, wherein the determining complexity of the predicted mask of the target layout based on a sum of perimeters of a plurality of graphics comprised in the target layout of the chip sample and a perimeter of the predicted mask of the target layout comprises:
calculating contour lines of the predicted mask of the target layout based on a sum of a square of a first derivative of the predicted mask of the target layout in an x direction and a square of a first derivative of the predicted mask of the target layout in a y direction;
performing summation on the contour lines of the predicted mask of the target layout to obtain the perimeter of the predicted mask of the target layout;
obtaining the sum L of perimeters of the plurality of graphics comprised in the target layout of the chip sample; and
calculating the complexity of the predicted mask of the target layout based on a result of dividing the perimeter of the predicted mask of the target layout by L.

19. The non-transitory computer-readable storage medium according to claim 17, wherein the adjusting a parameter of the mask generation model based on the target layout of the chip sample, the wafer pattern corresponding to the predicted mask of the target layout, the mask of the target layout, the predicted mask of the target layout, and the complexity of the predicted mask of the target layout until a training stop condition is met comprises:
constructing a first loss function based on the target layout of the chip sample and the wafer pattern corresponding to the predicted mask of the target layout;
constructing a second loss function based on the mask of the target layout and the predicted mask of the target layout;
constructing a target loss function based on the first loss function, the second loss function, and the complexity of the predicted mask of the target layout; and
adjusting the parameter of the mask generation model through a gradient descent algorithm based on the target loss function until the training stop condition is met.

20. The non-transitory computer-readable storage medium according to claim 17, wherein the mask generation model comprises an encoder and a decoder, the encoder comprises a plurality of convolutional neural network layers, and the decoder comprises a plurality of deconvolutional neural network layers.
